(19) United States
(12) Patent Application Publication
(10) Pub. No.: US 2007/0010094 A1
(43) Pub. Date: Jan. 11, 2007

(54) Method for depositing a conductive carbon material on a semiconductor for forming a Schottky contact and semiconductor contact device

(76) Inventors: Franz Kreupl, Munchen (DE); Gernot Steinlesberger, Munchen (DE)

Correspondence Address: JENKINS, WILSON, TAYLOR & HUNT, P. A., 3100 TOWER BLVD, SUITE 1200, DURHAM, NC, 27707, US

(21) Appl. No.: 11/495,808

(22) Filed: Jul. 28, 2006

Related U.S. Application Data
(63) Continuation of application No. PCT/EP04/14681, filed on Dec. 23, 2004.

(30) Foreign Application Priority Data
Feb. 10, 2004 (DE) 102004006544.6

(51) Int. Cl. H01L 21/44

(52) U.S. Cl. 438/674

(57) ABSTRACT

The invention relates to a method for depositing a conductive carbon material (17) on a semiconductor (14) for forming a Schottky contact (16). The inventive method comprises the following steps: introducing a semiconductor (14) into a process chamber (10); heating the interior (10′) of a process chamber (10) to a defined temperature; evacuating the process chamber (10) to a first defined pressure or below; heating the interior (10′) of a process chamber (10) to a second defined temperature; introducing a gas (12) which comprises at least carbon, until a second defined pressure is achieved which is higher than the first defined pressure; and depositing the conductive carbon material (17) on the semiconductor (14) from the gas (12) which comprises at least carbon, whereby the deposited carbon material (17) forms the Schottky contact (16) on the semiconductor (14).

### RELATED APPLICATIONS

This application is a continuation of PCT International Patent Application No. PCT/EP2004/014681, filed Dec. 23, 2004, which claims priority to German Patent Application No. 102004006544.6, filed Feb. 10, 2004, the disclosures of each of which are incorporated herein by reference in their entitety.

The present invention relates to a method for depositing a conductive carbon material on a semiconductor for forming a Schottky contact and a semiconductor contact device.

For a large number of components, for example diodes or transistors, based on a Schottky contact, it is extremely important to produce reproducible Schottky barriers having a sufficient barrier height. According to the prior art, metal, for example molybdenum, is deposited selectively over the semiconductor for forming a Schottky contact. Materials used hitherto have, e.g. in the case of silicon semiconductors, energy barriers of 0.55-0.85 eV (cf. SZE “Physics of Semiconductor”, 2nd edition, p. 245-311) and are difficult to pattern since metal has to be patterned selectively over the semiconductor. Metallization processes and the patterning thereof, in particular the use of heavy metals, do not meet the demands for a clean environment and processing that conserves resources.

A high conductivity is only one predefined stipulation for a gate material for a transistor. There are furthermore predefined stipulations regarding easy patternability, temperature stability up to 1200° Celsius and resistivity in relation to depletion of the charge carriers at the interface when a voltage is applied. The patternability, in particular, is problematic in the case of metallic electrodes since the patterning involving dry etching technology then has to stop with high selectivity on a thin gate oxide layer having a thickness of only approximately 1 nm, without attacking or even etching away said gate oxide layer. In the case of a Schottky contact it is necessary to stop on the semiconductor material and not on the gate oxide. What is more, deposition processes of metals (sputtering, CVD, PECVD . . . ) are cost-intensive single wafer processes.

Therefore, it is an object of the invention to provide a method for depositing a conductive carbon material on a semiconductor for forming a Schottky contact and a semiconductor contact device by means of which a low resistivity, a high energy barrier of the Schottky contact, high thermal stability, an environmentally friendly deposition and patterning method and a realization in a parallel process are made possible.

According to the invention, this object is achieved by means of the method for depositing a conductive carbon material on a semiconductor for forming a Schottky contact as specified in claim 1 and by means of the semiconductor contact device according to claim 18.

The idea on which the present invention is based essentially consists in depositing a highly conductive carbon layer from an organic gas conformally over a semiconductor for forming a Schottky contact, the Schottky contact providing a sufficiently high energy barrier.

In the present invention, the problem mentioned in the introduction is solved in particular by provision of a method for depositing a conductive carbon material on a semiconductor for forming a Schottky contact, comprising the steps of: heating the interior of a process chamber to a predetermined temperature; introducing the semiconductor into the process chamber; evacuating the process chamber to a first predetermined pressure or below the latter; heating the interior of a process chamber to a second predetermined temperature; introducing a gas, comprising at least carbon, until a second predetermined pressure is attained, which is higher than the first predetermined pressure; depositing the conductive carbon material on the semiconductor from the gas comprising at least carbon, the deposited carbon material on the semiconductor forming the Schottky contact.

Advantageous developments and refinements of the respective subject matter of the invention are found in the subclaims.

In accordance with one preferred development, the deposited carbon material on the semiconductor forms a Schottky diode.

In accordance with a further preferred development, the deposited carbon material on the semiconductor forms a Schottky gate of a MESFET transistor.

In accordance with a further preferred development, the first predetermined pressure lies below one Pa, preferably below one eighth of a Pa.

In accordance with a further preferred development, the second predetermined pressure lies within a range of between 10 and 1013 hPa, preferably between 300 and 700 hPa.

In accordance with a further preferred development, the predetermined temperature lies between 400° C. and 1200° C., and is preferably 600° C. or 950° C.

In accordance with a further preferred development, methane is introduced into the process chamber as the gas comprising at least carbon.

In accordance with a further preferred development, the gas is introduced into the process chamber so rapidly that, at a predetermined pressure, a deposition does not occur immediately, rather the gas first heats up and the deposition thereupon commences.

In accordance with a further preferred development, the deposited conductive carbon material is doped by the addition of diboran or BCI₃ or nitrogen or phosphorus or arsenic or by an ion implantation in a predetermined concentration.

One advantage of this preferred development is that the conductivity and the work function of the carbon material can be set by the doping of the deposited conductive carbon material.

In accordance with a further preferred development, prior to introducing the gas comprising at least carbon, a step of heat treatment of the semiconductor is carried out, preferably at the predetermined temperature, in particular in a hydrogen atmosphere with a pressure of between 200 and 500 Pa, preferably 330 Pa, for a predetermined duration, preferably 5 minutes.

In accordance with a further preferred development, after the deposition of the conductive carbon material, the latter is subjected to heat treatment at 1000° C. to 1200° C., preferably 1050° C., for a time duration of 0.5 to 5 minutes, preferably 2 minutes.

In accordance with a further preferred development, during the deposition of the conductive carbon material, the operation is interrupted after a predetermined time and the deposited conductive carbon material layer is partly etched back in an etching step, preferably using a plasma, after which the deposition operation is initiated again.

In accordance with a further preferred development, the interruption, the etching-back and the reinitiation of the deposition of the conductive carbon material are repeated multiply in a stage by stage process.

In accordance with a further preferred development, the deposition of the conductive carbon material is effected at a second predetermined pressure of between 1 and 300 hPa in the presence of an activating photon source in the process chamber.

In accordance with a further preferred development, the deposition of the conductive carbon material is carried out in parallel in a batch process or in a parallel process with a multiplicity of semiconductor wafers.

In accordance with a further preferred development, the deposition of the conductive carbon material is carried out in parallel in a batch process or in a parallel process with a multiplicity of semiconductor wafers as silicon semiconductors for a time duration of 2 to 30 minutes, preferably 5 minutes.

In this case, the duration of the deposition determines the thickness of the carbon layer. Given a typical duration of 5 minutes, the carbon layer is approximately 100 nanometers thick.

In accordance with a further preferred development, the Schottky contact has a Schottky barrier of at least 0.8 eV given a p-type doping of the silicon semiconductor of 10¹⁷/cm³.

Exemplary embodiments of the invention are illustrated in the drawings and are explained in more detail in the description below.

In the figures:

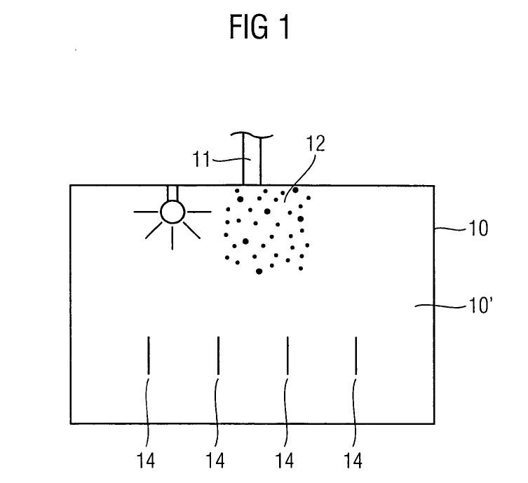

FIG. 1 shows a schematic side sectional view of a process chamber for elucidating one embodiment of the present invention;

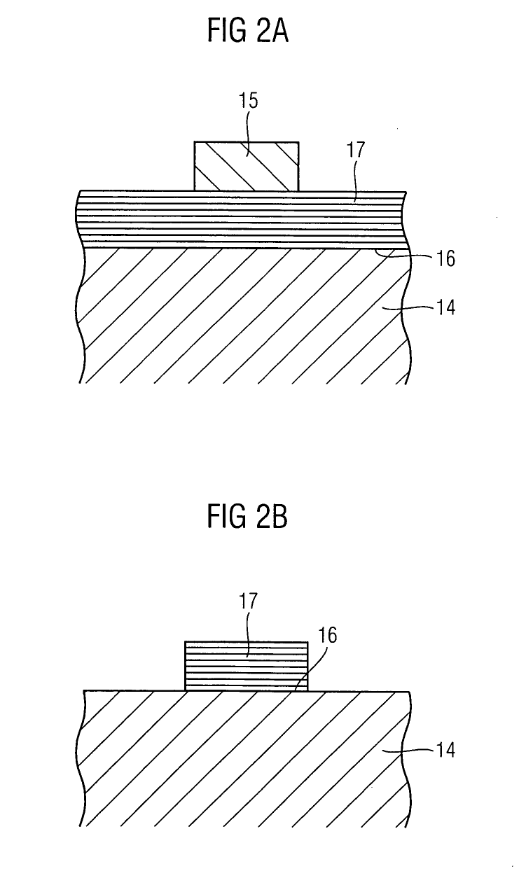

FIGS. 2a, b show a schematic cross-sectional view of a carbon material deposited over a semiconductor according to the present invention;

FIG. 3 shows a cross-sectional view of a Schottky diode according to the present invention;

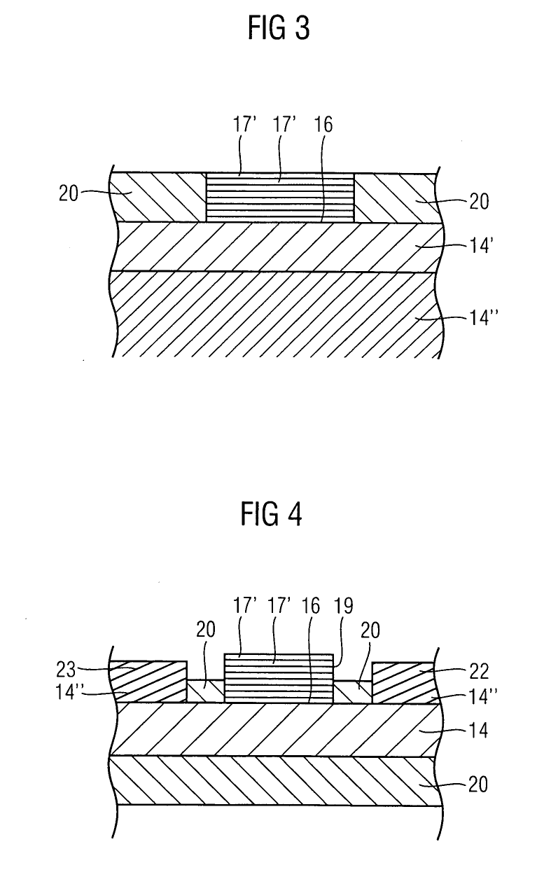

FIG. 4 shows a cross-sectional view of a Schottky gate of a MESFET according to the present invention.

In the figures, identical reference symbols designate identical or functionally identical component parts.

Although the present invention is described below with reference to semiconductor structures and semiconductor production processes, it is not restricted thereto, but rather can be used in diverse ways.

FIG. 1 shows a schematic side sectional view of a process chamber 10 for elucidating one embodiment of the present invention.

Any desired pressure can be applied to the process chamber 10 for example by means of a pump device (not shown). Any desired gases 12 can be introduced into the process chamber 10 via a supply line 11. By means of a heating device 13, which preferably also has a photon source, the temperature of the process chamber 10 can be regulated as desired, for example between 0° C. and 2000° C. In accordance with FIG. 1, a plurality of silicon semiconductors 14 for example in the form of a plurality of semiconductor wafers are arranged in the interior 10′ of the process chamber.

A deposition process according to the invention for forming a Schottky contact 16 is described below on the basis of an exemplary embodiment with reference to FIG. 1. Firstly, the process chamber 10, for example a furnace, is heated to a predetermined temperature, preferably 950° C., and has a first predetermined pressure of preferably below one eighth of a Pa applied to it after at least one semiconductor wafer 14, which is preferably initially at room temperature (20° C.) has been introduced into the interior 10′ of the process chamber 10.

This is followed preferably by a heat treatment step at 950° C. for a predetermined duration of, for example, 5 minutes with addition of hydrogen via the supply line 11, so that a pressure of approximately 330 Pa is present in the process chamber 10. The process chamber 10 is then filled with a gas 12, comprising at least carbon, preferably methane (CH4), at a second predetermined pressure within a range of between 300 and 800 hPa. In this case, the pyrolysis or decomposition of the gas 12 does not commence immediately, but rather preferably takes up approximately one minute until the gas 12 and the surface of the silicon semiconductor 14 have been heated to an extent such that the decomposition of the gas 12 commences at the surface of the silicon semiconductor 14.

FIG. 2a and FIG. 2b show a schematic cross-sectional view of a carbon material 17 deposited over a silicon semiconductor 14 for forming a Schottky contact 16 according to the present invention.

In accordance with FIG. 2a a conductive carbon material 17 is deposited over the semiconductor substrate 14 by the method explained by way of example with reference to FIG. 1. In order to pattern the deposited carbon material 17, a mask 15, e.g. a photoresist, is applied selectively over the carbon material 17. A subsequent patterning method, e.g. a lithography, forms the structure of the deposited carbon material 17 according to FIG. 2b. Between the deposited carbon material 17 and the semiconductor 14, the Schottky contact 16 is defined and determined by the junction of these two layers.

FIG. 3 shows a cross-sectional view of a preferred embodiment of a Schottky diode according to the present invention.

An n-doped semiconductor 14′ is applied over an n+-doped semiconductor 14″. Above the n-doped semiconductor 14′, a cutout is provided in a patterned insulating layer 20. With reference to FIGS. 2a, b, the conductive carbon material 17 is deposited in the cutout of the patterned insulating layer 20 by means of a plurality of carbon material layers 17′.

The Schottky diode illustrated in FIG. 3 is only by way of example both in terms of the choice of the doping of the silicon semiconductors 14 (and 14′, 14″) and in terms of the choice of the structural construction.

The carbon material 17 substitutes the metal layer of any known Schottky diode (cf. SZE “Physics of Semiconductor”, 2nd edition, p. 245-311).

FIG. 4 illustrates a cross-sectional view of a preferred embodiment of a Schottky gate of a MESFET according to the present invention.

The MESFET 21 has a semiconductor layer 14 over an insulating layer 20, preferably silicon oxide. A further insulating layer 20 with three patterned cutouts is provided over the semiconductor layer 14, an n+-doped semiconductor layer 14″ for forming the drain and the source of the MESFET respectively being deposited in the two outer patterned cutouts. In the third, central cutout of the patterned insulating layer 20, the carbon material 17 is deposited with reference to FIG. 2.

A Schottky contact 16 is formed between the carbon material layer 17 and the semiconductor 14.

As in FIG. 3, according to FIG. 4, too, the choice of the dopings of the semiconductor materials (14, 14′, 14″) and also the choice of the structural construction of the MESFET are only by way of example.

The Schottky gate 19, formed by carbon material layers 17′ or carbon material 17, in each case substitutes the metallic gate of any known MESFET transistor (cf. T.J. Thornton “Physics and Applications of the Schottky Junction Transistor”, IEEE Transactions on Electron Devices, vol. 48, no. 10, October 2001, p. 2421).

In this case, a semiconductor substrate may be a solid body composed of the following materials:
silicon
silicon carbide;
diamond;
germanium;
at least one of the III-V semiconductors BN, BP, BAs, AIN, AIP, AlAs, AlSb, GaN, GaP, GaAs, GaSb, InN, InP, InAs, InSb;
at least one of the II-VI semiconductors ZnO, ZnS, ZnSe, ZnTe, CdS, CdSe, CdTe, HgS, HgSe, HgTe, BeS, BeSe, BeTe, MgS, MgSe;
at least one of the compounds GeS, GeSe, GeTe, SnS, SnSe, SnTe, PbO, PbS, PbSe, PbTe,
at least one of the compounds CuF, CuCI, CuBr, Cul, AgF, AgCI, AgBr, AgI;
or composed of a combination of said materials.

The semiconductor may be p-doped or n-doped.

Although the present invention has been described above on the basis of preferred exemplary embodiments, it is not restricted thereto, but rather can be modified in diverse ways. Thus, the method can also be applied to other substrates or carrier materials apart from semiconductor substrates.

List of reference symbols
10 Process chamber
10′ Interior of the process chamber
11 Supply line into process chamber
12 Gaseous medium
13 Heating device, preferably with photon source
14 Semiconductor, e.g. silicon semiconductor
14′ n-doped semiconductor
14″ n+-doped semiconductor
15 Mask, e.g. photoresist
16 Schottky contact
17 Carbon material
17′ Carbon material layer
18 Schottky diode
19 Schottky gate of a MESFET (metal semiconductor FET, metal semiconductor field effect transistor)
20 Silicon oxide, SiO₂
21 MESFET
22 Source of the MESFET
23 Drain of the MESFET

What is claimed is:

1. A method for depositing a conductive carbon material (17) on a semiconductor (14) for forming a Schottky contact (16), comprising the steps of:
(a) introducing the semiconductor (14) into the process chamber;
(b) heating the interior (10′) of a process chamber (10) to a predetermined temperature; (10);
(c) evacuating the process chamber (10) to a first predetermined pressure or below the latter;
(d) heating the interior (10′) of a process chamber (10) to a second predetermined temperature;
(e) introducing a gas (12), comprising at least carbon, until a second predetermined pressure is attained, which is higher than the first predetermined pressure; and
(f) depositing the conductive carbon material (17) on the semiconductor (14) from the gas (12) comprising at least carbon, the deposited carbon material (17) on the semiconductor (14) forming the Schottky contact (16).

2. The method as claimed in claim 1, characterized in that the semiconductor (14) is made from one of the following materials: from silicon; from silicon carbide; from diamond; from germanium; from at least one of the III-V semiconductors BN, BP, BAs, AIN, AIP, AlAs, AlSb, GaN, GaP, GaAs, GaSb, InN, InP, InAs, InSb; from at least one of the II-VI semiconductors ZnO, ZnS, ZnSe, ZnTe, CdS, CdSe, CdTe, HgS, HgSe, HgTe, BeS, BeSe, BeTe, MgS, MgSe; from at least one of the compounds GeS, GeSe, GeTe, SnS, SnSe, SnTe, PbO, PbS, PbSe, PbTe; from at least one of the compounds CuF, CuCI, CuBr, Cul, AgF, AgCI, AgBr, AgI; or from a combination of said materials.

3. The method as claimed in claim 1, characterized in that the semiconductor (14) is p-doped or n-doped.

4. The method as claimed in claim 1, characterized in that the deposited carbon material (17) on the semiconductor (14) forms a Schottky diode (18).

5. The method as claimed in claim 1, characterized in that the deposited carbon material (17) on the semiconductor (14) forms a Schottky gate (19) of a MESFET transistor.

6. The method as claimed in one of the preceding claims, characterized in that the first predetermined pressure lies below one Pa, preferably below one eighth of a Pa.

7. The method as claimed in one of the preceding claims, characterized in that the second predetermined pressure lies within the range of between 10 and 1013 hPa, preferably between 300 and 700 hPa.

8. The method as claimed in one of the preceding claims, characterized in that the predetermined temperature lies between 400° C. and 1200° C., and is preferably 600° C. or 950° C.

9. The method as claimed in one of the preceding claims, characterized in that methane is introduced into the process chamber (10) as the gas (12) comprising at least carbon.

10. The method as claimed in one of the preceding claims, characterized in that the gas (12) is introduced into the process chamber (10) so rapidly that, at a predetermined pressure, a deposition does not occur immediately, rather the gas first heats up and the deposition thereupon commences.

11. The method as claimed in one of the preceding claims, characterized in that the deposited conductive carbon material (17) is doped by the addition of diboran or BCI₃ or nitrogen or phosphorus or arsenic or by an ion implantation in a predetermined concentration.

12. The method as claimed in one of the preceding claims, characterized in that prior to introducing the gas (12) comprising at least carbon, a step of heat treatment of the silicon semiconductor (14) is carried out, preferably at the predetermined temperature, in particular in a hydrogen atmosphere with a pressure of between 200 and 500 Pa, preferably 330 Pa, for a predetermined duration, preferably 5 min.

13. The method as claimed in one of the preceding claims, characterized in that after the deposition of the conductive carbon material (17), the latter is subjected to heat treatment at 1000° C. to 1200° C., preferably 1050° C., for a time duration of 0.5 to 5 minutes, preferably 2 minutes.

14. The method as claimed in one of the preceding claims, characterized in that during the deposition of the conductive carbon material (17), the operation is interrupted after a predetermined time and the deposited conductive carbon material layer (17′) is partly etched back in an etching step, preferably using a plasma, after which the deposition operation is initiated again.

15. The method as claimed in one of the preceding claims, characterized in that the interruption, the etching-back and the reinitiation of the deposition of the conductive carbon material (17) are repeated multiply in a stage by stage process.

16. The method as claimed in one of the preceding claims, characterized in that the deposition of the conductive carbon material (17) is effected at a second predetermined pressure of between 1 and 300 hPa in the presence of an activating photon source (13) in the process chamber (10).

17. The method as claimed in one of the preceding claims, characterized in that the deposition of the conductive carbon material (17) is carried out in parallel in a batch process with a multiplicity of semiconductor wafers (14).

18. The method as claimed in one of the preceding claims, characterized in that the deposition of the conductive carbon material (17) is carried out in parallel in a batch process with a multiplicity of semiconductor wafers (14) for a time duration of 2 to 30 minutes, preferably 5 minutes.

19. The method as claimed in one of the preceding claims, characterized in that the Schottky contact (16) has a Schottky barrier of at least 0.8 eV given a p-type doping of the semiconductor (14).

20. The method as claimed in one of the preceding claims, characterized in that the carbon layer (17) is patterned using a hydrogen, oxygen or air plasma and a photoresist.

21. A semiconductor contact device comprising:
(a) a semiconductor (14); and
(b) a conductive Schottky contact (16) made from a deposited carbon material (17) over the semiconductor (14), the deposited carbon material (17) over the semiconductor (14) forming a Schottky diode (18).

22. The semiconductor contact device as claimed in claim 21, characterized in that the deposited carbon material (17) over the semiconductor (14) forms a Schottky gate (19) of a MESFET transistor.

23. The semiconductor contact device as claimed in either of claims 21 and 22, characterized in that the carbon material (17) comprises boron, nitrogen, phosphorus or arsenic by means of the addition of diboran or BCI₃ or nitrogen or phosphine or arsine during the process or an ion implantation after the process in a predetermined concentration as doping.
